(19) United States
(12) Patent Application Publication
(10) Pub. No.: US 2009/0160011 A1
(43) Pub. Date: Jun. 25, 2009

(54) ISOLATOR AND METHOD OF MANUFACTURING THE SAME

(75) Inventor: Young Jin PARK, Yuseong-Gu (KR)

Correspondence Address: HORIZON IP PTE LTD, 7500A Beach Road, #04-306/308 The Plaza, SINGAPORE 199591, SG

(73) Assignee: PETARI INCORPORATION, Yuseong-Gu (KR)

(21) Appl. No.: 12/343,460

(22) Filed: Dec. 23, 2008

(30) Foreign Application Priority Data
Dec. 24, 2007 (KR) 10-2007-0136168

(51) Int. Cl. H01L 23/58; H01L 21/762

(52) U.S. Cl. 257/506; 438/404; 438/125; 257/E21.545

(57) ABSTRACT

The present invention relates to an isolator and a method of manufacturing the same. An isolator according to the present invention includes a silicon wafer, protective devices formed in predetermined regions of the silicon wafer, and a transformer formed in a predetermined region on the silicon wafer, the transformer having at least two coil patterns spaced apart from each other. According to the present invention, an isolator can be protected from impulses generated by ESD and surge, so that its reliability can be improved, and its size can be considerably decreased. Further, the number of wire bonding times is decreased, so that performance of a chip can be enhanced, and packaging efficiency can be improved, thereby increasing productivity.

### CROSS REFERENCE TO RELATED APPLICATION

This application claims priority to Korean Patent application No. 10-2007-0136168, filed on Dec. 24, 2007 and all the benefits accruing therefrom under 35 U.S.C. 119, the contents of which are herein incorporated by reference in its entirety.

### FIELD OF THE INVENTION

The present invention relates to an isolator, and more particularly, to an isolator and a method of manufacturing the same.

### BACKGROUND

An isolator is a circuit device that is interposed between electronic instruments or devices or their components to cut off an electrical path formed therebetween. In an electronic instrument or device, an isolator is used when an interference phenomenon occurs due to a ground loop necessarily generated while ground potential is changed between systems, between semiconductor chips or between circuit blocks, when a power bucking phenomenon occurs between semiconductor chips or between different kinds of circuit blocks, or when a driving impedance problem of circuits or the like occurs. The isolator functions to cut off an electrical path between the electronic instrument or device and a power source. The isolator is also used in effectively distributing, amplifying and converting signals.

Generally, isolators may be divided into an opto-coupler type isolator and a transformer type isolator depending on isolation methods. The opto-coupler type isolator is applied to only digital circuits. Since high power consumption is required due to low efficiency of individual optical devices, the opto-coupler type isolator is not suitable for small-sized mobile instruments. On the other hand, since power is easily transferred, the transformer type isolator may be applied to analog circuits or systems. However, since an isolation function is optimized in an isolation state of about 500 Vrms, the transformer type isolator may be damaged when an impulse generated by ESD and surge is applied thereto. Further, since an input stage, an output stage and a transformer stage are separately manufactured and then implemented as a single package, the transfer efficiency is very low, and the size of a chip is considerably increased.

### SUMMARY

The present invention provides a transformer type isolator capable of being protected from ESD and surge and a method of manufacturing the isolator.

The present invention also provides an isolator, wherein ESD and surge protective circuits and a transformer are simultaneously formed on the same wafer to thereby reducing the size of a device, and a method of manufacturing the isolator.

The present invention also provides an isolator, wherein a transformer is implemented using a semiconductor package to thereby minimize the price and size of a device and improving its temperature characteristic, and a method of manufacturing the isolator.

According to an aspect of the present invention, there is provided an isolator including a silicon wafer; protective devices formed in predetermined regions of the silicon wafer; and a transformer formed in a predetermined region on the silicon wafer, and provided with at least two coil patterns spaced apart from each other.

The silicon wafer may be a high-resistance silicon wafer. A high-resistance region may be formed in a portion of the silicon wafer. The high-resistance region may include an oxide layer formed in a predetermined region of the silicon wafer.

The protective devices may include diodes respectively formed at one and the other sides of the transformer.

The protective devices may be connected to electronic devices that are respectively positioned at one and the other sides of the transformer through wirings.

The protective devices may be connected to electronic devices that are respectively positioned at one and the other sides of the transformer through bonding wires.

According to another aspect of the present invention, there is provided an isolator including a package substrate; and a transformer formed in a predetermined region on the package substrate, and provided with at least two coil patterns spaced apart from each other, wherein the transformer is connected to a semiconductor chip mounted on the package substrate through a bonding wire.

The coil patterns may be formed on top and bottom surfaces of the package substrate respectively.

The coil pattern formed on the bottom surface of the package substrate may be coated with a material having excellent heat dissipation and insulating properties.

According to a further aspect of the present invention, there is provided a method of manufacturing an isolator, which includes forming at least two protection devices spaced apart from each other in predetermined regions of a silicon wafer; forming a first insulating layer on the silicon wafer, forming a lower coil pattern on the first insulating layer, and forming lower wirings connected to the protective devices; and forming a second insulating layer on the entire structure of the silicon wafer, an upper coil pattern on the second insulating layer, and forming upper wirings partially connected to the lower wirings.

The silicon wafer may be a high-resistance silicon wafer manufactured by irradiating a silicon ingot with neutrons or implanting impurities and then cutting the silicon ingot; or by irradiating a cut silicon wafer with neutrons or implanting impurities.

An oxide layer is formed on a portion of the silicon wafer. A porous region may be formed by ion-implanting impurities into a predetermined region of the silicon wafer; and the oxide layer may be formed by heat-treating the porous region under an oxygen atmosphere. A porous region may be formed by using anodization cell employing a platinum cathode and a silicon wafer anode that are immersed in Hydrogen Fluoride (HF) electrolyte; and the oxide layer may be formed by heat-treating the porous region under an oxygen atmosphere.

The oxide layer may be formed by forming a plurality of trenches having a predetermined width and depth in a predetermined region of the silicon wafer and then heat-treating the plurality of trenches under an oxygen atmosphere.

The protective device may be formed by forming a first impurity region in a predetermined region of the silicon wafer and then forming a second impurity region in the first impurity region.

According to a still further aspect of the present invention, there is provided a method of manufacturing an isolator, which includes forming a plurality of holes on the package substrate; forming an upper coil pattern and upper wirings on a top surface of the package substrate, and forming a lower coil pattern and lower wirings on a bottom surface of the package substrate; mounting semiconductor chips on the top surface of the package substrate and then connecting the semiconductor chips and the upper wirings; molding a top surface of the package substrate; and filling the plurality of holes with a conductive material and then connecting solder balls to the plurality of holes, respectively.

The method may further include coating the bottom surface of the package substrate with a material having excellent heat dissipation and insulation properties after forming the lower coil pattern and the lower wirings.

A protective device may be formed in a predetermined region of the semiconductor chip, and the protective device may be connected to the upper wirings.

### BRIEF DESCRIPTION OF THE DRAWINGS

FIGS. 1A to 1E are sectional views sequentially illustrating a method of manufacturing an isolator according to a first embodiment of the present invention;

FIG. 2 is a perspective plan view of the isolator according to the first embodiment of the present invention;

FIG. 3 is a schematic view of the isolator according to the present invention;

FIGS. 4A to 4C are sectional views sequentially illustrating a method of manufacturing an isolator according to a second embodiment of the present invention;

FIGS. 5A to 5C are sectional views sequentially illustrating a method of manufacturing an isolator according to a third embodiment of the present invention;

FIGS. 6A to 6C are sectional views sequentially illustrating a method of manufacturing an isolator according to a fourth embodiment of the present invention; and

FIG. 7 is a sectional view of an isolator according to a fifth embodiment of the present invention.

### DETAILED DESCRIPTION

Hereinafter, exemplary embodiments of the present invention will be described in detail with reference to the accompanying drawings. However, the present invention is not limited to the embodiments disclosed below but may be implemented into different forms. These embodiments are provided only for illustrative purposes and for full understanding of the scope of the present invention by those skilled in the art. In the drawings, the thicknesses of layers and regions are exaggerated for clarity, and like reference numerals are used to designate like elements throughout the specification and drawings. Further, an expression that an element such as a layer, region, substrate or plate is placed on or above another element indicates not only a case where the element is placed directly on or just above the other element but also a case where a further element is interposed between the element and the other element.

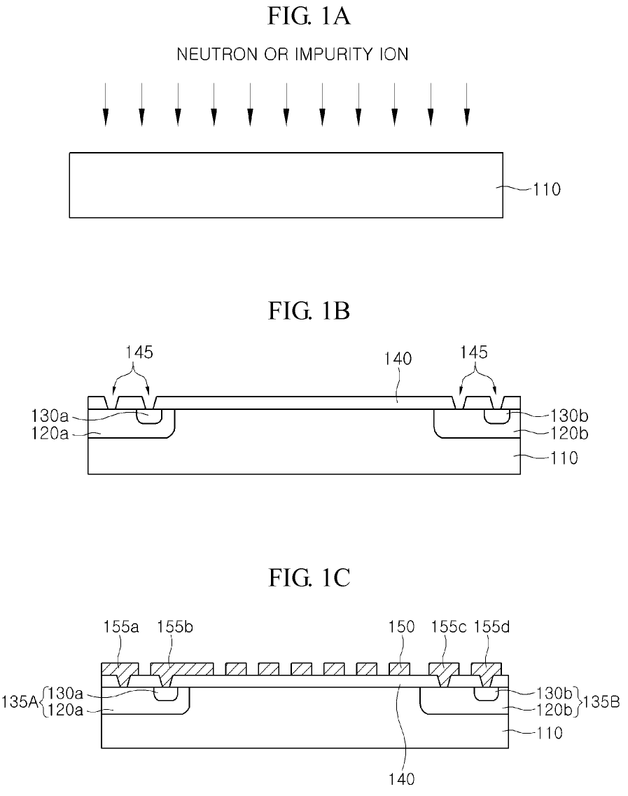

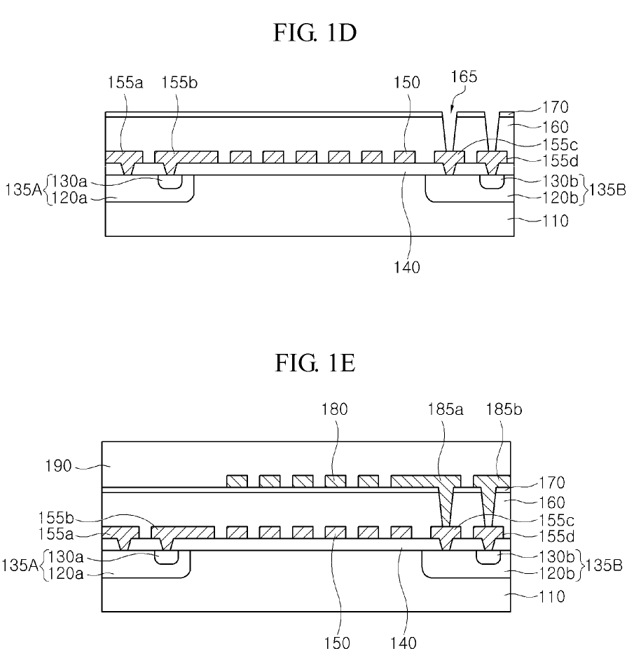

FIGS. 1A to 1E are sectional views sequentially illustrating a method of manufacturing an isolator according to a first embodiment of the present invention. FIG. 2 is a perspective plan view of the isolator according to the first embodiment of the present invention.

Referring to FIG. 1A, a high-resistance silicon wafer 110 is manufactured by irradiating a silicon wafer prepared by the Czochralski method with neutrons or ion-implanting impurities. The process of changing a silicon wafer into the high-resistance silicon wafer 110 by irradiating the silicon wafer with neutrons will be described as follows. Generally, in case of a p-type silicon wafer prepared by the Czochralski method, its specific resistivity is about 10 Ω-cm, and the concentration of boron doped with a p-type impurity is about 1×10¹²/cm³. If such a silicon wafer is irradiated with neutrons, isotope Si³⁰ is changed into Si³¹, and then into P³¹ by going through beta (β) decay. Free electrons of the P³¹ made as described above are recombined with holes originated from boron, so that a p-type silicon wafer is changed into an intrinsic silicon wafer. As a result, a high-resistance silicon wafer 110 having a specific resistivity of 10 Ω-cm or more may be manufactured from a silicon wafer prepared by the Czochralski method, in which manufacturing cost is low and the growth of large-sized single crystalline silicon is possible. Here, its specific resistivity can be adjusted by controlling neutron irradiation density and time. For example, a high-resistance silicon wafer 110 having a specific resistivity of 100 kΩ-cm or more may be manufactured by irradiating a silicon wafer having a specific resistivity of 38 Ω-cm with neutrons having a flux of 2 to 3×10¹³n/cm²·sec for 2 to 10 hours. At this time, as the irradiation time of neutrons is increased, the specific resistivity of a wafer is increased. Meanwhile, the high-resistance semiconductor substrate 110 may be manufactured by irradiating a rod-shaped silicon ingot prepared by the Czochralski method with neutrons and then cutting the silicon ingot to a predetermined thickness, or by cutting a silicon ingot prepared by the Czochralski method to a predetermined thickness and then irradiating the silicon ingot with neutrons. Alternatively, a high-resistance silicon wafer 110 having a large specific resistivity may also be manufactured by performing an impurity ion implantation process instead of the neutron irradiation process.

Referring to FIG. 1B, a plurality of first impurity regions 120a and 120b are formed by performing a first impurity ion implantation process on predetermined regions of the high-resistance silicon wafer 110. A plurality of second impurity regions 130a and 130b are formed in the first impurity regions 120a and 120b by performing a second ion implantation process. Here, the first impurity regions 120a and 120b and the second impurity regions 130a and 130b are formed by ion-implanting different impurities. For example, the first impurity regions 120a and 120b are formed by ion-implanting a p-type impurity, and the second impurity regions 130a and 130b are formed by ion-implanting an n-type impurity. Accordingly, p-n junction diodes are formed, which serve as ESD and surge protective circuits 135A and 135B. In addition, a non-conductive layer 140 is formed on the high-resistance silicon wafer 110, and predetermined regions of the non-conductive layer 140 are then etched by a predetermined photolithography and etching process, thereby forming a plurality of first contact holes 145 for respectively exposing the first impurity regions 120a and 120b and the second impurity regions 130a and 130b. The non-conductive layer 140 is formed to improve characteristics of a transformer, and formed using an oxide layer, a poly-silicon layer having a large specific resistivity, or a nitride layer.

Referring to FIG. 1C, after a first conductive layer is formed on the non-conductive layer 140 to fill the plurality of first contact holes 145, a predetermined photolithography and etching process is performed thereon, thereby patterning the first conductive layer. Accordingly, formed on the non-conductive layer 140 are a lower coil pattern 150 wound at a predetermined number of turns and a plurality of lower wirings 155a, 155b, 155c and 155d respectively connected to the first and second impurity regions 120a, 130a, 120b and 130b. The lower wirings 155a, 155b, 155c and 155d are spaced apart from one another. Particularly, one side of the lower coil pattern 150 extends and is connected to the lower wiring 155b, and the lower wiring 155a extends to the outside of the isolator and is connected to a semiconductor chip, circuit or system positioned at one side of the isolator. The lower wiring 155c is not connected to the lower coil pattern 150, and the lower wiring 155d does not extend to the outside. Here, the lower coil pattern 150 may be formed in a coil shape, which is wound outward while spinning clockwise from the center thereof or outward while spinning counterclockwise from the center thereof.

Referring to FIG. 1D, a first insulating layer 160 is formed on the entire structure of the silicon wafer 110. The first insulating layer 160 is planarized to a sufficient thickness so that it does not have a stepped portion over the first conductive layer 150. A nitride layer 170 is formed on the first insulating layer 160. The nitride layer 170 is formed to improve an adhesion property to a second conductive layer which will be formed later. Second contact holes 165 for respectively exposing the lower wirings 155c and 155d are formed by etching predetermined regions of the nitride layer 170 and the first insulating layer 160.

Referring to FIG. 1E, a second conductive layer is formed on the nitride layer 170 to fill the second contact holes 165 and then patterned by a predetermined photolithography and etching process. Accordingly, an upper coil pattern 180 is formed in a coil shape wound at a predetermined number of turns, and upper wirings 185a and 185b are formed to be connected to the lower wirings 155c and 155d through the second contact holes 165, respectively. The upper coil pattern 180 is formed in a coil shape wound in a direction opposite to the direction in which the lower coil pattern 150 is wound. That is, when the lower coil pattern 150 is formed in a coil shape wound outward while spinning clockwise from the center thereof, the upper coil pattern 180 may be formed in a coil shape wound outward while spinning counterclockwise from the center thereof. When the lower coil pattern 150 is formed in a coil shape wound outward while spinning counterclockwise from the center thereof, the upper coil pattern 180 may be formed in a coil shape wound outward while spinning clockwise from the center thereof. One side of the upper coil pattern 180 extends and is connected to the upper wiring 185a, and the upper wiring 185a is spaced apart from the upper wiring 185b. The upper wiring 185a extends to the outside of the isolator and is connected to a semiconductor chip, circuit or system positioned at the other side of the isolator. A second insulating layer 190 is formed on the entire structure, wherein the second insulating layer is formed to a sufficient thickness, considering its heat dissipation property.

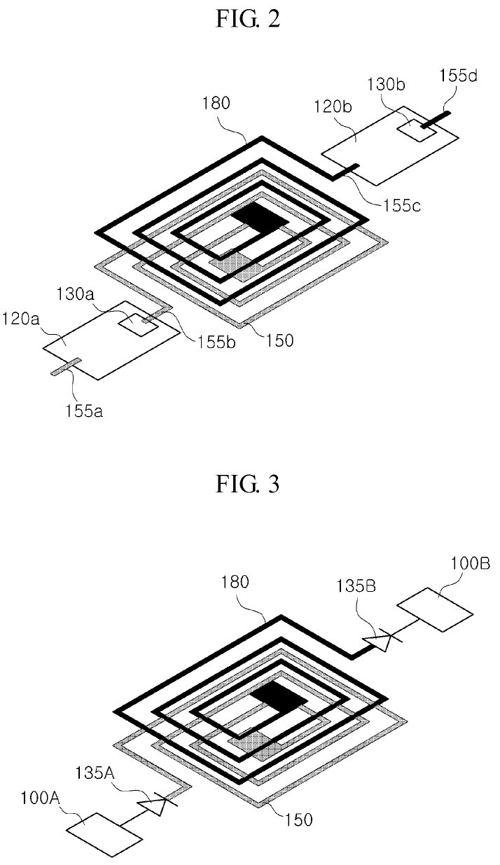

In the transformer type isolator according to the first embodiment of the present invention, as shown in FIG. 3, a semiconductor chip, circuit or system 100A positioned at one side of the isolator is connected to the circuit protective device 135A, such as a diode, and the lower coil pattern 150, and a semiconductor chip, circuit or system 100B positioned at the other side of the isolator is connected to the circuit protective device 135B and the upper coil pattern 180. An electrical path between semiconductor chips, circuits or systems respectively positioned at one and the other sides of the isolator can be cut off by such a transformer type isolator, and the transformer type isolator can be protected from an impulse generated by ESD and surge.

The transformer type isolator according to the first embodiment of the present invention is implemented on a high-resistance silicon wafer, and a lower wiring extending to the outside of the isolator and an upper wiring extending to the outside of the isolator are semiconductor chips, circuits or systems positioned at one and the other sides of the isolator, respectively. However, the transformer type isolator may be connected to semiconductor chips, circuits or systems positioned at one and the other sides thereof not using lower and upper wirings but using wire bonding. Hereinafter, a method of manufacturing a transformer type isolator connected to the outside using such wire bonding will be described. Here, the descriptions overlapping with the first embodiment of the present invention will be briefly described.

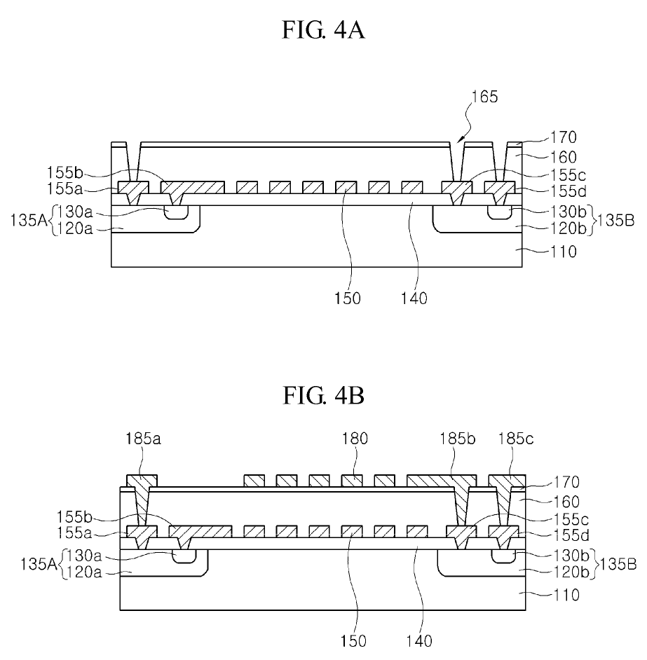

Referring to FIG. 4A, first impurity regions are respectively formed in predetermined regions of a high-resistance silicon wafer 110 manufactured by irradiating a silicon wafer with neutrons or ion-implanting impurities, and second impurity regions 130a and 130b are then formed in the first impurity regions 120a and 120b, respectively. A non-conductive layer 140 is formed over the entire structure, and predetermined regions of the non-conductive layer 140 are then etched, thereby forming a plurality of first contact holes 145 for respectively exposing the first impurity regions 120a and 120b and the second impurity regions 130a and 130b. A first conductive layer is formed on the non-conductive layer to fill the first contact holes 145 and then patterned by performing a predetermined photolithography and etching process. Accordingly, formed on the non-conductive layer 140 are a lower coil pattern 150 wound at a predetermined number of turns and a plurality of lower wirings 155a, 155b, 155c and 155d respectively connected to the first and second impurity regions 120a, 130a, 120b and 130b. The lower wirings 155a, 155b, 155c and 155d are formed to be spaced apart from one another, and one side of the lower coil pattern 150 extends and is connected to the lower wiring 155b. The lower wirings 155a and 155d do not extend to the outside of the isolator.

Referring to FIG. 4B, a first insulating layer 160 and a nitride layer 170 are formed over the entire structure, and a second contact holes 165 for selectively exposing the lower wirings 155a, 155c and 155d are formed by etching predetermined regions of the nitride layer 170 and the first insulating layer 160. A second conductive layer is formed on the nitride layer 170 to fill the second contact holes 165 and then patterned by a predetermined photolithography and etching process. Accordingly, an upper coil pattern 180 is formed in a coil shape wound at a predetermined number of turns, and a plurality of upper wirings 185a, 185b and 185c are formed to be connected to the lower wirings 155a, 155c and 155d through the second contact holes 165, respectively. Here, the upper wiring 185a is spaced apart from the upper coil pattern 180, and the other side of the upper coil pattern 180 extends and is connected to the upper wiring 185b. The upper wiring 185c is spaced apart from the upper wiring 185b and does not extend to the outside.

Referring to FIG. 4C, a second insulating layer 190 is formed to a sufficient thickness on the entire structure of the silicon wafer 110, considering its heat dissipation property. The upper wirings 185a and 185c are exposed by etching predetermined regions of the second insulating layer 190. Bonding wires 200a and 200b are formed to be connected to the upper wirings 185a and 185c, respectively. Accordingly, the upper wirings 185a and 185c are connected to semiconductor chips, circuits or systems positioned at one and the other sides of the isolator through the bonding wires 200a and 200b, respectively.

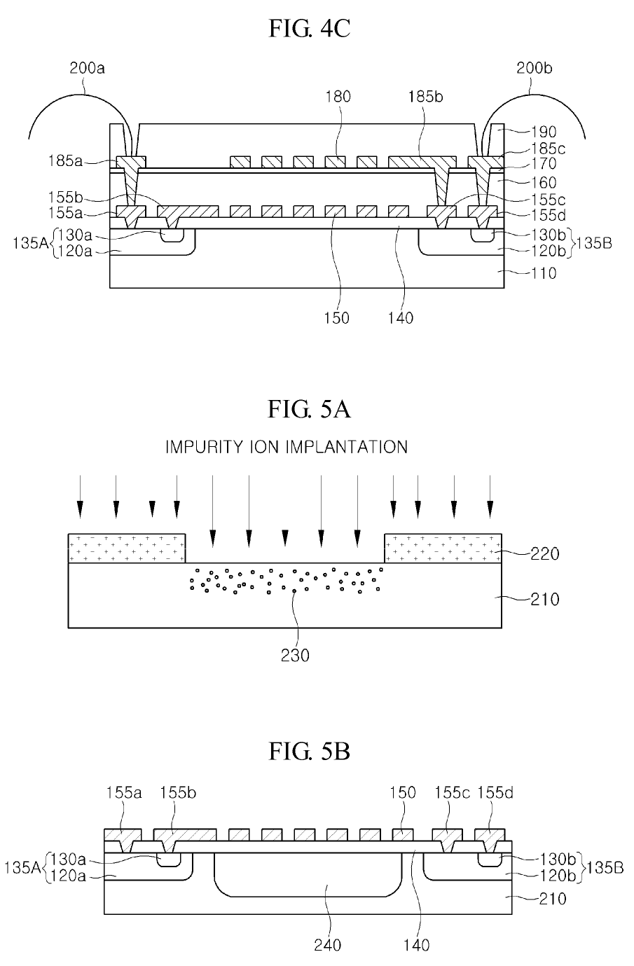

A transformer type isolator having protective devices according to the first and second embodiments of the present invention is implemented on a high-resistance silicon wafer manufactured by irradiating a silicon wafer with neutrons or ion-implanting impurities. However, the transformer type isolator according to the present invention may be implemented on a partially high-resistance silicon wafer. Hereinafter, an isolator according to a third embodiment of the present invention will be described with reference to FIGS. 5A to 5C.

Referring to FIG. 5A, a photoresist 220 is formed on a silicon wafer 210, and a predetermined region of the silicon wafer 210 is then exposed by performing an exposure and development process on a predetermined region of the photoresist 220. Preferably, the predetermined region of the silicon wafer 210 exposed by the photoresist 220 is a region in which a transformer will be formed. A porous region 230 is formed on the silicon wafer 210 using such an impurity ion implantation process.

Referring to FIG. 5B, after the photoresist 220 is removed, the porous region 230 formed on the silicon wafer 210 is oxidized by performing a heat treatment process, whereby an oxide layer 240 is formed on the silicon wafer 210. First impurity regions 120a and 120b are respectively formed in predetermined regions of the silicon wafer 210 in which the oxide layer 240 is not formed, and second impurity regions 130a and 130b are then formed in the first impurity regions 120a and 120b, respectively. Accordingly, p-n junction diodes are formed, which serve as circuit protective devices 135A and 135B for protecting circuits from ESD or surge. Thereafter, a non-conductive layer 140 is formed on the entire structure, and predetermined regions of the non-conductive layer 140 are then etched, thereby forming first contact holes for respectively exposing the second impurity regions 130a and 130b. A first conductive layer is formed on the non-conductive layer 140 to fill the first contact holes and then is patterned by performing a predetermined photolithography and etching process. Accordingly, formed on the non-conductive layer 140 are a lower coil pattern 150 formed in a coil shape wound at a predetermined number of turns and a plurality of lower wirings 155a, 155b, 155c and 155d respectively connected to the first and second impurity regions 120a, 130a, 120b and 130b. One side of the lower coil pattern 150 extends and is connected to the lower wiring 155b, and the lower wiring 155a extends to the outside of the isolator and is connected to a semiconductor chip, circuit or system positioned at one side of the isolator. The lower wirings 155c and 155d are spaced apart from each other, and the lower wiring 155d does not extend to the outside.

Referring to FIG. 5C, a first insulating layer 160 and a nitride layer 170 are formed over the entire structure of the silicon wafer 210. Then, second contact holes for respectively exposing the lower wirings 155c and 155d are formed by etching predetermined regions of the nitride layer 170 and the first insulating layer 160. A second conductive layer is formed on the nitride layer 170 to fill the second contact holes and then patterned by a predetermined photolithography and etching process. Accordingly, an upper coil pattern 180 formed in a coil shape wound at a predetermined number of turns, and upper wirings 185a and 185b are formed to be connected to the lower wirings 155c and 155d through the second contact holes, respectively. The upper coil pattern 180 is connected to the upper wiring 185a, and the upper wiring 185b extends to the outside and is connected to a semiconductor chip, circuit and system positioned at the other side of the isolator. A second insulating layer 190 is formed on the entire structure of the silicon wafer 210, wherein the second insulating layer 190 is formed to a sufficient thickness, considering its heat dissipation property.

Meanwhile, a porous region 230 is formed by ion-implanting impurities into a predetermined region of the silicon wafer or by using anodization cell employing a platinum cathode and a silicon wafer anode that are immersed in Hydrogen Fluoride (HF) electrolyte; and the oxide layer 240 is then formed by heat-treating the porous region under an oxygen atmosphere.

The transformer type isolator according to the third embodiment of the present invention is manufactured by forming the transformer type isolator according to the first embodiment of the present invention on a silicon wafer which is partially implanted with ions and then oxidized. However, the isolator according to the third embodiment of the present invention may be applied to the transformer type isolator according to the second embodiment of the present invention using wire bonding. That is, a transformer type isolator may be manufactured by performing wire bonding using a silicon wafer which is partially implanted with ions and then oxidized.

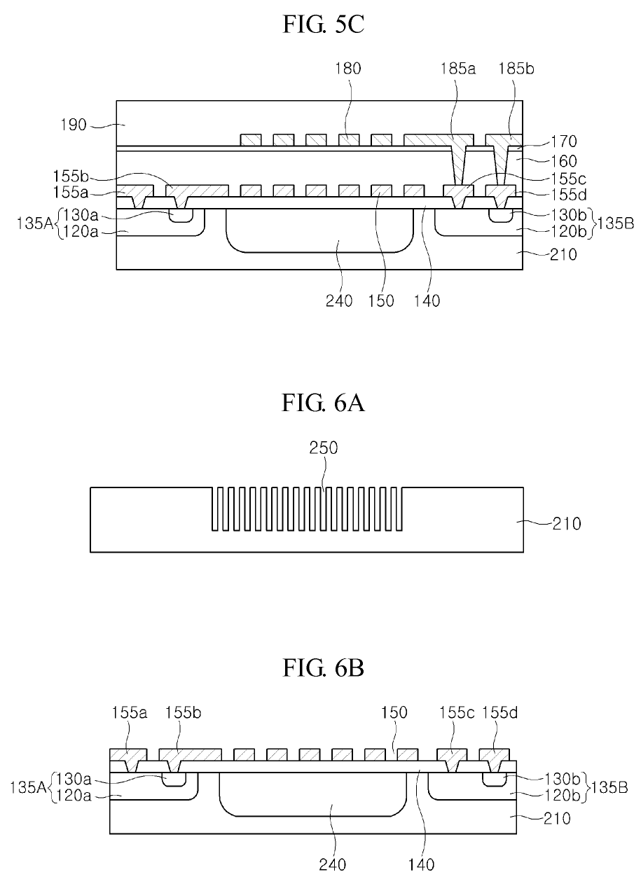

A method of partially etching a predetermined region of a silicon wafer and then oxidizing using a heat treatment process may be used as another method of forming a transformer type isolator on a partially high-resistance silicon wafer. Hereinafter, an isolator using such a method according to a fourth embodiment of the present invention will be described with reference to FIGS. 6A to 6C.

Referring to FIG. 6A, a predetermined region of a silicon wafer 210 is repeatedly etched to a predetermined width and depth plural times. That is, a plurality of trenches 250 having a predetermined width and depth are formed on the silicon wafer 210 having a region in which a transformer will be formed.

Referring to FIG. 6B, the plurality of trenches 250 formed on the silicon wafer 210 are oxidized by performing a heat treatment process, whereby an oxide layer 240 is formed on the silicon wafer 210. In order to form the oxide layer 240, a heat treatment process is performed under an oxygen atmosphere using a reaction gas containing oxygen. At this time, a hard mask or the like is preferably formed in the other region except for the region in which the transformer will be formed so that the other region is not oxidized. If a heat treatment process is performed under an oxygen atmosphere, a thin silicon wafer 210 between the trenches 250 is oxidized, and the trenches 250 are filled by the oxidation, thereby forming an oxide layer 240. Thereafter, first impurity regions 120a and 120b are formed in the predetermined regions of the silicon wafer 20 in which the oxide layer 240 is not formed, and second impurity regions 130a and 130b are then formed in the first impurity regions 120a and 120b, respectively. Accordingly, p-n junction diodes are formed, which serve as circuit protective devices 135A and 135B for protecting circuits from ESD or surge. Subsequently, after a non-conductive layer 140 is formed on the entire structure of the silicon wafer 210, first contact holes for respectively exposing the second impurity regions 130a and 130b are formed by etching predetermined regions of the non-conductive layer 140. A first conductive layer is formed on the non-conductive layer 140 to fill the first contact holes and then patterned by performing a predetermined photolithography and etching process. Accordingly, formed on the non-conductive layer 140 are a lower coil pattern 150 formed in a coil shape wound at a predetermined number of turns and a plurality of lower wirings 155a, 155b, 155c and 155d respectively connected to the first and second impurity regions 120a, 130a, 120b and 130b. One side of the lower coil pattern 150 extends and is connected to the lower wiring 155b, and the lower wiring 155a extends to the outside of the isolator and is connected to a semiconductor chip, circuit or system positioned at one side of the isolator. The lower wirings 155c and 155d are spaced apart from each other, and the lower wiring 155d does not extend to the outside.

Referring to FIG. 6C, a first insulating layer 160 and a nitride layer 170 are formed over the entire structure of the silicon wafer 210. Then, second contact holes for respectively exposing the lower wirings 155c and 155d are formed by etching predetermined regions of the nitride layer 170 and the first insulating layer 160. A second conductive layer is formed on the nitride layer 170 to fill the second contact holes and then patterned by a predetermined photolithography and etching process. Accordingly, an upper coil pattern 180 is formed in a coil shape wound at a predetermined number of turns, and upper wirings 185a and 185b are formed to be connected to the lower wirings 155c and 155d through the second contact holes, respectively. The upper coil pattern 180 is connected to the upper wiring 185a, and the upper wiring 185b extends to the outside of the isolator and is connected to a semiconductor chip, circuit or system positioned at the other side of the isolator. A second insulating layer 190 is formed on the entire structure of the silicon wafer 210, wherein the second insulating layer 190 is formed to a sufficient thickness, considering its heat dissipation property.

Of course, the isolator according to the fourth embodiment of the present invention may be applied to the transformer type isolator according to the second embodiment of the present invention using wire bonding. That is, a transformer type isolator may be manufactured by performing wire bonding using a silicon wafer which is partially etched and then oxidized so that a partial oxide layer is formed on the silicon wafer.

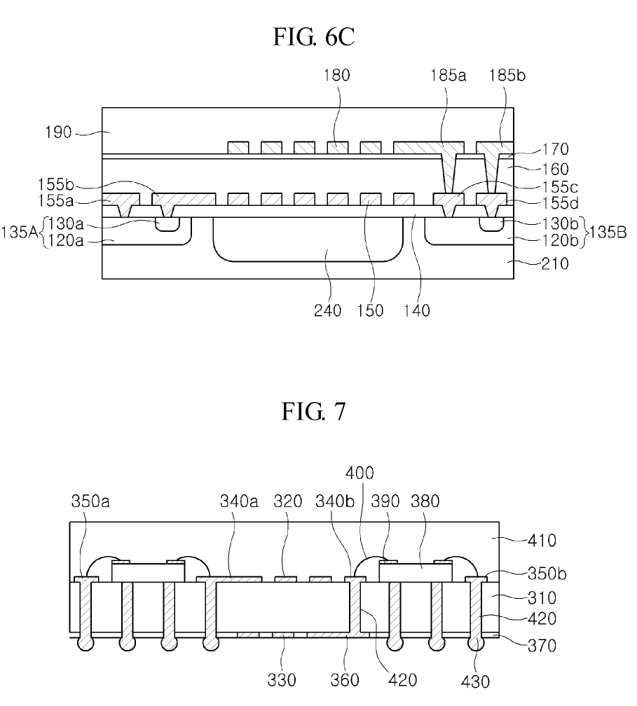

Meanwhile, the transformer type isolator according to the present invention may be implemented by forming a transformer on a ball grid array (BGA) package substrate. Hereinafter, a transformer implemented on such a BGA package substrate will be described with reference to FIG. 7.

Referring to FIG. 7, upper and lower coil patterns 320 and 330 are respectively formed in predetermined regions on top and bottom surfaces of a substrate 310 using a conductive layer, preferably copper. A first upper wiring 340a is formed to extend to a side from the upper coil pattern 320, and a second upper wiring 340b is formed to be spaced apart from the upper coil pattern 320. Pads 350a and 350b are respectively formed to be spaced apart from the first and second upper wirings 340a and 340b at a predetermined distance, preferably to have a region in which a chip is mounted. When the lower coil pattern 330 is formed, a lower wiring 360 is formed to extend to a side from the lower coil pattern 330, and the second upper wiring 340b and the lower wiring 360 are connected to each other through a conductive layer filled in contact holes. A protective layer 370 is formed on the bottom surface of the substrate 310 having the lower coil pattern 330 and the lower wiring 360 to isolate the substrate 310 from the outside, wherein the protective layer 370 is formed of a material having excellent heat dissipation and insulation properties. Semiconductor chips 380, at one and the other sides of which circuit protective devices are formed, are respectively formed in predetermined regions on the top surface of the substrate 310, i.e., a region between the first upper wiring 340a and the pad 350a and a region between the second upper wiring 340b and the pad 350b. A plurality of bump electrodes 390 spaced apart from each other at a predetermined distance are formed in predetermined regions on each of the semiconductor chips 380. Preferably, one side of the bump electrode 390 is connected the circuit protective device formed on the semiconductor chip 380. The bump electrodes 390 are electrically connected to the first and second upper wirings 340a and 340b and the pads 350a and 350b through bonding wires 400, respectively. A molding resin 410 such as an epoxy molding compound (EMC) is applied to protect the semiconductor chips 380, the bonding wires 400 and the like from the external environment. A plurality of holes 420 are formed in the substrate 310 from the bottom thereof, and the plurality of holes 420 are filled with a conductive material. Solder balls 430 are electrically connected to the holes 420 filled with the conductive material, respectively. The solder ball 430 is electrically connected to the semiconductor chip 380 through the hole 420 filled with the conductive material, so that external electric signals can be inputted to the semiconductor chip 380 through the solder ball 430, and data can be outputted to the outside through the solder ball 430. Particularly, if the solder ball 430 is used as a power voltage terminal or ground power terminal, an electrical connection distance is shortened, thereby decreasing inductance and resistance. The solder ball 430 also allows heat generated from the semiconductor chip 380 to be dissipated to the outside.

In an isolator implemented as described above, the size of a package can be remarkably decreased, and heat dissipation characteristics can be improved.

As described above, according to the present invention, a protective device and a transformer are simultaneously formed on a high-resistance silicon wafer or a silicon wafer in which an oxide layer is partially formed, thereby protecting an isolator from impulses generated by ESD and surge. Accordingly, reliability can be improved, and the size of a chip can be considerably decreased. Further, the number of wire bonding times is decreased, thereby improving performance of the chip, and the packaging efficiency is improved, thereby increasing productivity.

In addition, an isolator can be implemented using a BGA substrate, so that a parasitic effect caused by wire bonding can be remarkably reduced. Also, the performance of a chip can be considerably enhanced, and heat dissipation characteristics of upper and lower coil patterns of a transformer can be remarkably improved. Further, a substrate having a semiconductor chip and a transformer is packaged, so that the size of the isolator can be remarkably decreased.

What is claimed is:

1. An isolator, comprising:
a silicon wafer;
protective devices formed in predetermined regions of the silicon wafer; and
a transformer formed in a predetermined region on the silicon wafer, and provided with at least two coil patterns spaced apart from each other.

2. The isolator as claimed in claim 1, wherein the silicon wafer is a high-resistance silicon wafer.

3. The isolator as claimed in claim 1, wherein a high-resistance region is formed in a portion of the silicon wafer.

4. The isolator as claimed in claim 3, wherein the high-resistance region comprises an oxide layer formed in a predetermined region of the silicon wafer.

5. The isolator as claimed in claim 1, wherein the protective devices comprise diodes respectively formed at one and the other sides of the transformer.

6. The isolator as claimed in claim 1, wherein the protective devices are connected to electronic devices that are respectively positioned at one and the other sides of the transformer through wirings.

7. The isolator as claimed in claim 1, wherein the protective devices are connected to electronic devices that are respectively positioned at one and the other sides of the transformer through bonding wires.

8. An isolator, comprising:
a package substrate; and
a transformer formed in a predetermined region on the package substrate, and provided with at least two coil patterns spaced apart from each other,
wherein the transformer is connected to a semiconductor chip mounted on the package substrate through a bonding wire.

9. The isolator as claimed in claim 8, wherein the coil patterns are formed on top and bottom surfaces of the package substrate, respectively.

10. The isolator as claimed in claim 9, wherein the coil pattern formed on the bottom surface of the package substrate is coated with a material having excellent heat dissipation and insulating properties.

11. A method of manufacturing an isolator, comprising:
forming at least two protection devices spaced apart from each other in predetermined regions of a silicon wafer;
forming a first insulating layer on the silicon wafer, forming a lower coil pattern on the first insulating layer, and forming lower wirings connected to the protective devices; and
forming a second insulating layer on the entire structure of the silicon wafer, an upper coil pattern on the second insulating layer, and forming upper wirings partially connected to the lower wirings.

12. The method of claim 11, wherein the silicon wafer is a high-resistance silicon wafer manufactured by irradiating a silicon ingot with neutrons or implanting impurities and then cutting the silicon ingot; or by irradiating a cut silicon wafer with neutrons or implanting impurities.

13. The method of claim 11, wherein an oxide layer is formed on a portion of the silicon wafer.

14. The method of claim 13, wherein a porous region is formed by ion-implanting impurities into a predetermined region of the silicon wafer; and the oxide layer is formed by heat-treating the porous region under an oxygen atmosphere.

15. The method of claim 13, wherein a porous region is formed by using anodization cell employing a platinum cathode and a silicon wafer anode that are immersed in Hydrogen Fluoride (HF) electrolyte; and the oxide layer is formed by heat-treating the porous region under an oxygen atmosphere.

16. The method of claim 13, wherein the oxide layer is formed by forming a plurality of trenches having a predetermined width and depth in a predetermined region of the silicon wafer and then heat-treating the plurality of trenches under an oxygen atmosphere.

17. The method of claim 11, wherein the protective device is formed by forming a first impurity region in a predetermined region of the silicon wafer and then forming a second impurity region in the first impurity region.

18. A method of manufacturing an isolator, comprising:
forming a plurality of holes on the package substrate;
forming an upper coil pattern and upper wirings on a top surface of the package substrate, and forming a lower coil pattern and lower wirings on a bottom surface of the package substrate;
mounting semiconductor chips on the top surface of the package substrate and then connecting the semiconductor chips and the upper wirings;
molding the top surface of the package substrate; and
filling the plurality of holes with a conductive material and then connecting solder balls to the plurality of holes, respectively.

19. The method of claim 18, further comprising coating the bottom surface of the package substrate with a material having excellent heat dissipation and insulation properties after forming the lower coil pattern and the lower wirings.

20. The method of claim 18, wherein a protective device is formed in a predetermined region of the semiconductor chip, and the protective device is connected to the upper wirings.
